(19) United States
(12) Patent Application Publication
(10) Pub. No.: US 2009/0261461 A1
(43) Pub. Date: Oct. 22, 2009

(54) SEMICONDUCTOR PACKAGE WITH LEAD INTRUSIONS

(76) Inventors: Steven Sapp, Felton, CA (US); Chung-Lin Wu, San Jose, CA (US); Maria Christina B. Estacio, Lapulapu City (PH); Bigildis Dosdos, San Jose, CA (US); Hamza Yilmaz, Saratoga, CA (US)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/104,182

(22) Filed: Apr. 16, 2008

(51) Int. Cl. H01L 23/495; H01L 21/60

(52) U.S. Cl. 257/666; 438/123; 257/E23.031; 257/E21.51

(57) ABSTRACT

Semiconductor packages comprising a plurality of lead fingers containing a lead intrusion at the edge of the lead fingers are described. The semiconductor packages comprise an integrated circuit chip that is connected to a die pad and is electrically connected to multiple lead fingers. One or more of the lead fingers may have a lead intrusion disposed on the external exposed lower surface of the lead finger. The lead intrusion may have a height that is about ⅕ to about ½ the height of a lead finger, a width that is about ⅕ to about 1/2 the width of a lead finger, and a depth that is about ¼ to about ¾ the length of the externally exposed lower surface of a lead finger. The lead intrusion increases the area on the lead finger that contacts a bond material, such as solder, and therefore increase the strength of the joint between the semiconductor package and an external surface to which the lead finger is connected (i.e., a PCB). The lead intrusion allows out gassing during reflow of the bond material which may reduce voiding. The lead intrusion can also increase bond joint reliability by providing longer crack propagation length.

### FIELD

This application relates generally to packaged semiconductor devices or semiconductor packages. More specifically, this application relates to semiconductor packages comprising a plurality of lead fingers containing a lead intrusion at the edge of the lead fingers.

### BACKGROUND

Semiconductor packages are well known in the art. Generally, these packages may include one or more semiconductor devices, such as an integrated circuit die or chip, which may be connected to a die pad that is centrally formed in a lead frame. In some cases, bond wires electrically connect the integrated circuit chip to a series of lead fingers that serve as an electrical connection to an external device (i.e., a printed circuit board or PCB). An encapsulating material covers the bond wires, integrated circuit chip, lead fingers, and other components of the semiconductor device to form the exterior of the semiconductor package. In this manner, an integrated circuit chip may be protected from environmental hazards—such as moisture, contaminants, corrosion, and mechanical shock—while being electrically and mechanically connected to an intended device external to the semiconductor package.

After an integrated circuit chip has been produced and encapsulated in a semiconductor package, the chip may be used in an ever growing variety of electronic applications, such as disk drives, USB controllers, portable computer devices, cellular phones, and so forth. Depending on the chip and the application, these integrated circuit chips and semiconductor packages may be highly miniaturized as well as highly integrated.

Most conventional semiconductor packages, however, have one or more shortcomings. For instance, the externally exposed lower surface of the lead fingers in some conventional semiconductor packages may be flat. A flat lower surface of the externally exposed lead fingers may result in a weakening of the bond or solder joint between the package and an external surface to which it is connected (i.e., the surface of a printed circuit board or PCB). Semiconductor packages with lead fingers that have a flat lower surface may also detach from the external surface at one or more critical locations. This detachment may often occur when a larger package has a higher pin count and has a longer distance to the neutral point (the center of the package).

To overcome some of these shortcomings, it has been proposed to increase the solder joint strength between the semiconductor package and the external surface by forming a depression on the externally exposed lower surface of the lead fingers. These depressions may add additional area on the bottom surface of the lead fingers to which solder may be applied when the package is secured to the PCB. The additional area provided by the depression may fuse with the solder and strengthen solder joint strength between the semiconductor package and the external surface.

Nevertheless, such depressions also have shortcomings. For instance, the depressions may not provide proper venting for out gassing during reflow and may be susceptible to solder voids between the lead finger and the external surface. This solder void may actually reduce solder joint strength. As well, the shape of the depressions may make it harder to form a proper solder fillet at an edge the lead finger.

### BRIEF SUMMARY

This application relates to semiconductor packages comprising a plurality of lead fingers containing a lead intrusion at the edge of the lead fingers. The semiconductor packages comprise an integrated circuit chip that is connected to a die pad and is electrically connected to multiple lead fingers. One or more of the lead fingers may have a lead intrusion disposed on the external lower surface of the lead finger. The lead intrusion may have a height that is about ⅕ to about ½ the height of a lead finger, a width that is about ⅕ to about ½ the width of a lead finger, and a depth that is about ¼ to about ¾ the length of the lower surface of the lead finger. The lead intrusion increases the area on the lead finger that contacts a bond material, such as solder, and therefore increase the strength of the joint between the semiconductor package and an external surface to which the lead finger is connected (i.e., a PCB). The lead intrusion allows out gassing during reflow of the solder material which may reduce voiding. The lead intrusion can also increase bond joint reliability by providing longer crack propagation length.

### BRIEF DESCRIPTION OF THE DRAWINGS

The following description can be better understood in light of several Figures, in which:

FIG. 1 contains an illustration of a cross-sectional view of some embodiments of a semiconductor package with lead intrusions;

FIG. 2 contains an exemplary view of a single lead finger with a lead intrusion; and

FIGS. 3A, 3B, 4A, 4B, 5A, 5B, 6A, and 6B contain views of several different embodiments of a lead finger with a lead intrusion.

The Figures illustrate specific aspects of the semiconductor devices and associated methods of making and using such devices. Together with the following description, the Figures demonstrate and explain the principles of the semiconductor devices and associated methods. In the drawings, the thickness of layers and regions are exaggerated for clarity. It will also be understood that when a layer is referred to as being “on” another layer or substrate, it can be directly on the other layer or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and methods for making and using such device can be implemented and used without employing these specific details. For example, while the description focuses on semiconductor devices, it can be modified to be used in other electrical devices that are packaged, such as substrate types of packages and MEMS devices. As well, while the description focuses on devices using wire bonding, it could also be used in other interconnection types, like ball grid array connections, flip chip on leadframes, and chip on lead packages. Finally, while the following detailed description focuses on implementing lead intrusions in dual flat no lead package (DFN) or quad flat no lead package (QFN), the described lead intrusions may be implemented with any type of semiconductor package.

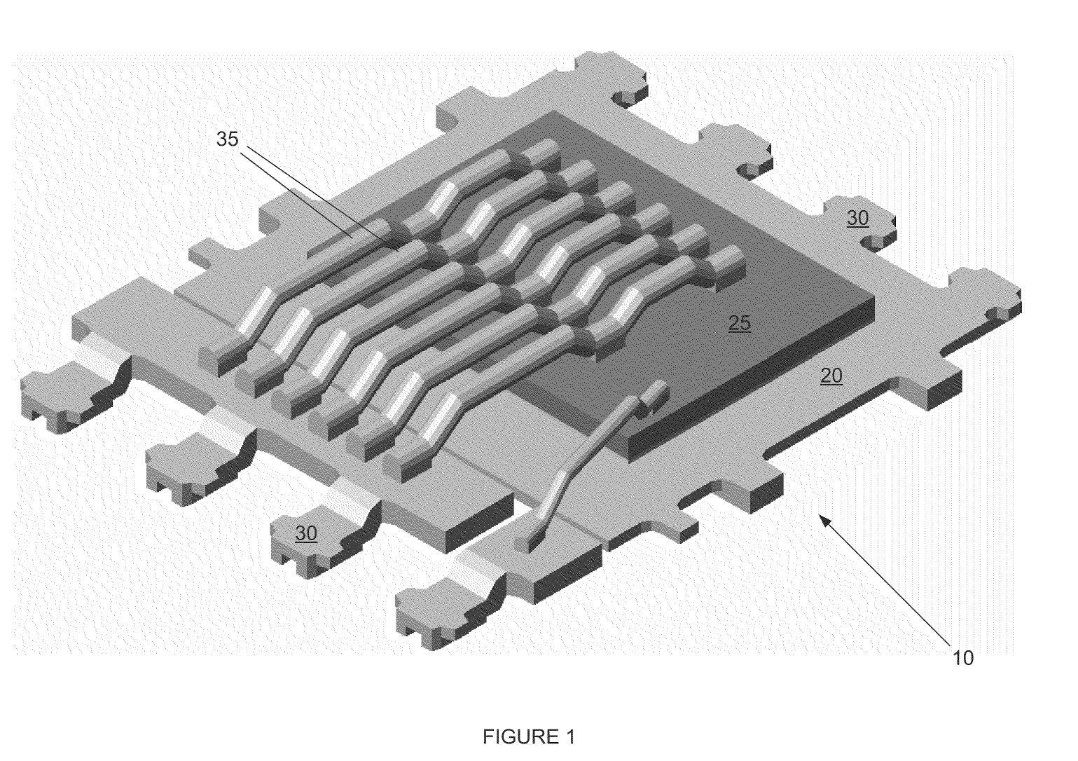

The Figures illustrate some embodiments of a semiconductor package 10 with lead intrusions 15 located at an edge thereof. FIG. 1 illustrates that the semiconductor package 10 may generally comprise any suitable integrated circuit chip 20, die pad 25, plurality of lead fingers 30, plurality of bond wires 35, and encapsulation material (not shown). The semiconductor package 10 may contain any known or novel component suitable for semiconductor packages that is not depicted in FIG. 1, including die attach material, tie bars, dam bars.

Although the semiconductor package 10 may include any number of integrated circuit chips, FIG. 1 depicts that in some embodiments the integrated circuit chip 20 may include one chip 20. The chip 20 may be any known integrated circuit chip. For example, the chip may be made of silicon, GaAs, SiC, GaN, or any other suitable semiconductor material. Similarly the chip 20 may include one or more discrete transistors, diodes, integrated circuits, or other suitable integrated circuit.

FIG. 1 illustrates that the integrated circuit chip 20 may include an upper surface that is available for connection and a lower surface that rests on the die pad 25. In some embodiments, the upper surface of the chip 20 may have a plurality of conventional input and/or bond pads as known in the art. Moreover, the lower surface of the integrated circuit chip 20 may be connected to an upper surface of the die pad 25 of the lead frame in any suitable manner. Some non-limiting examples of methods for connecting the integrated circuit chip 20 to an upper surface the die pad 25 may include the use of a non-conductive chemical adhesive, a conductive adhesive (e.g., PbSn or lead free solder paste, silver epoxy, etc.), a mechanical connection (e.g., a conventional clip), and so forth.

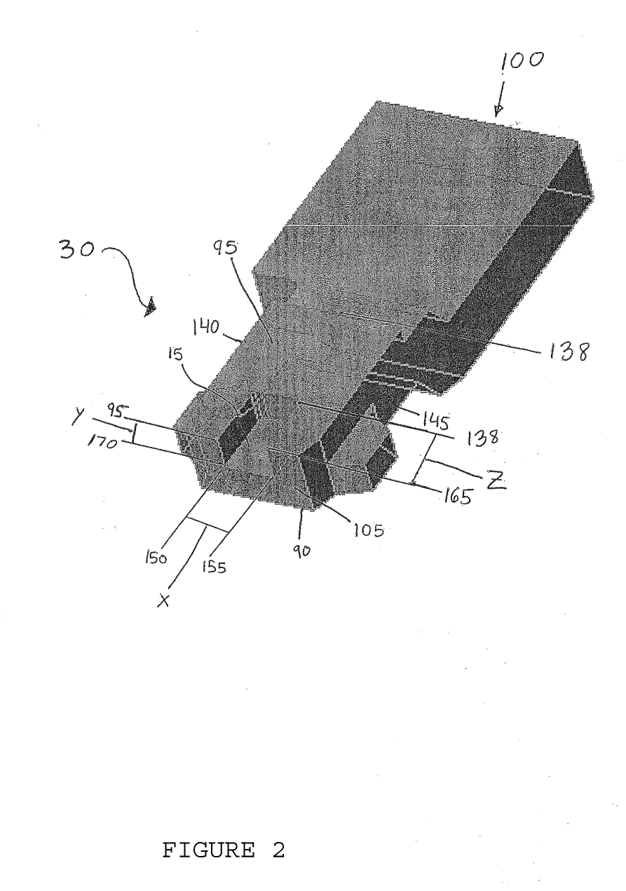

FIGS. 1 and 2 show that the semiconductor package 10 may include a plurality of lead fingers 30. The lead fingers 30 may comprise any type of conductive lead fingers 30 commonly known in the art, such as those formed from any conductive materials like substantially pure copper, copper alloy, and alloy 42.

As shown in FIG. 1, the lead fingers 30 may, in some embodiments, be formed at regular (or non-regular) intervals adjacent to one or more side surfaces of the die pad 25. For instance, the lead fingers 30 may be formed at regular intervals adjacent to two or four side surfaces of the die pad 25. The lead fingers 30 extend away from the die pad 25 while being spaced apart from the side surfaces of the die pad 25.

In some embodiments, the lead fingers 30 and the die pad 25 are not in direct contact with each other. At the same time, though, they are electrically connected together through any manner known in the art. For instance, the integrated circuit chip 20 and the lead fingers may be electrically connected by wire bonding; ribbon bonding; copper clips; solder bumps, balls, or studs; and/or other methods. Indeed, in the embodiments shown in FIG. 1, one or more conventional bond wires 35 made from any suitable conductive material may be electrically connected between each lead finger 30 and the integrated circuit chip 20. In some embodiments, the upper surface 90 of the lead fingers 30 may even be electroplated with a conductive material, such as silver, lead, aluminum, or gold to improve the electrical connection between the lead fingers 30 and the integrated circuit chip 20. Additionally, when used, the bond wires 35 may be electrically connected to the lead fingers 30 and the bond pads of the chip 20 through any known technique such as gold, copper, aluminum, silver wire bonding, copper clip bonding, thermocompression bonding, ultrasonic bonding, and the like.

The lead fingers 30 may be either an input lead finger or an output lead finger. The lead finger 30 that is electrically connected to an input bond pad on the chip 20 may be called an input lead finger. Likewise, the lead finger 30 that is electrically connected to an output bond pad of the chip 20 may be called the output lead finger.

Although not shown, the integrated circuit chip 20, die pad 25, lead fingers 30, bond wires 35, and/or any other desired components may be encapsulated in a suitable encapsulation or molding material. Some non-limiting examples of suitable encapsulation materials 40 may include thermoset resins—such as silicones, phenolics, and epoxies—and thermoplastics. Moreover, the encapsulating material may be formed around the desired components in any suitable manner. Some non-limiting examples of suitable methods for encapsulating the desired components may include injection of the encapsulation material, transfer molding, or other appropriate methods.

As shown in FIG. 2, the lead fingers 30 may include an upper surface 90, a lower surface 95, a proximal side surface 100, and a distal side surface 105. The proximal surface 100 of the lead finger 30 is located closer to the die pad 25 while the distal surface 105 is located further away from the die pad 25.

The lead fingers 30 may also include a lead intrusion 15. While the Figures illustrate that each lead finger 30 contains a single intrusion 15, in other embodiments each lead finger may contain multiple intrusions 15. In yet other embodiments, not every lead finger 30 needs to contain an intrusion 15.

The semiconductor package 10 may comprise any type of lead intrusion 15 with any characteristic that increases solder joint strength between the lead finger 30 and the external surface to which it is connected (i.e., the surface of a PCB). In some embodiments, the lead intrusions 15 may be disposed on one or more of the lead fingers 30 so as to open from the lower surface 95 of the lead finger 30 as well as to extend to and open from any desired edge of the lead finger 30. Some non-limiting examples of edges of the lead finger 30 may include the proximal end surface 138 of the externally exposed lower surface 95 and the distal side surface 105, as illustrated in FIG. 2.

FIG. 2 illustrates an example of a lead finger 30 that is flipped over to show the lower surface 95 of the lead finger 30. As shown in the embodiments shown in FIG. 2, the lead intrusion 15 may be disposed distally on the lead finger 30 so as to extend to and open from the distal side surface 105 of the lead finger 30. Moreover, FIG. 2 illustrates that the lead intrusion 15 may be disposed on the lower surface 95 of the lead fingers 30 so as to open to the lower surface 95. FIG. 2 also illustrates that the lead intrusion 15 may comprise a first side 150, and a second side 155, a proximal end 160, and a distal end 165 disposed at the distal side surface 105 of the lead finger 30.

The lead intrusions 15 may be any shape that allows for increased solder joint strength between the lead finger 30 of the semiconductor package 10 and the exterior surface, as well as any shape that allows for out-gassing during solder reflow. For instance, at the edge (e.g., the distal side surface 105) of the lead finger 30 to which the lead intrusion 15 extends, the lead intrusion 15 may have any desired profile or geometry. For instance, at the distal side surface 105 of the lead finger 30, the lead intrusion 15 may have a profile that is substantially rounded, square shaped, rectangular, triangular, ellipse, or any other shape that allows it to have the properties mentioned above. For instance, FIG. 2 depicts a lead finger 30 wherein the lead intrusion 15 has a substantially rectangular profile at the distal side surface 105.

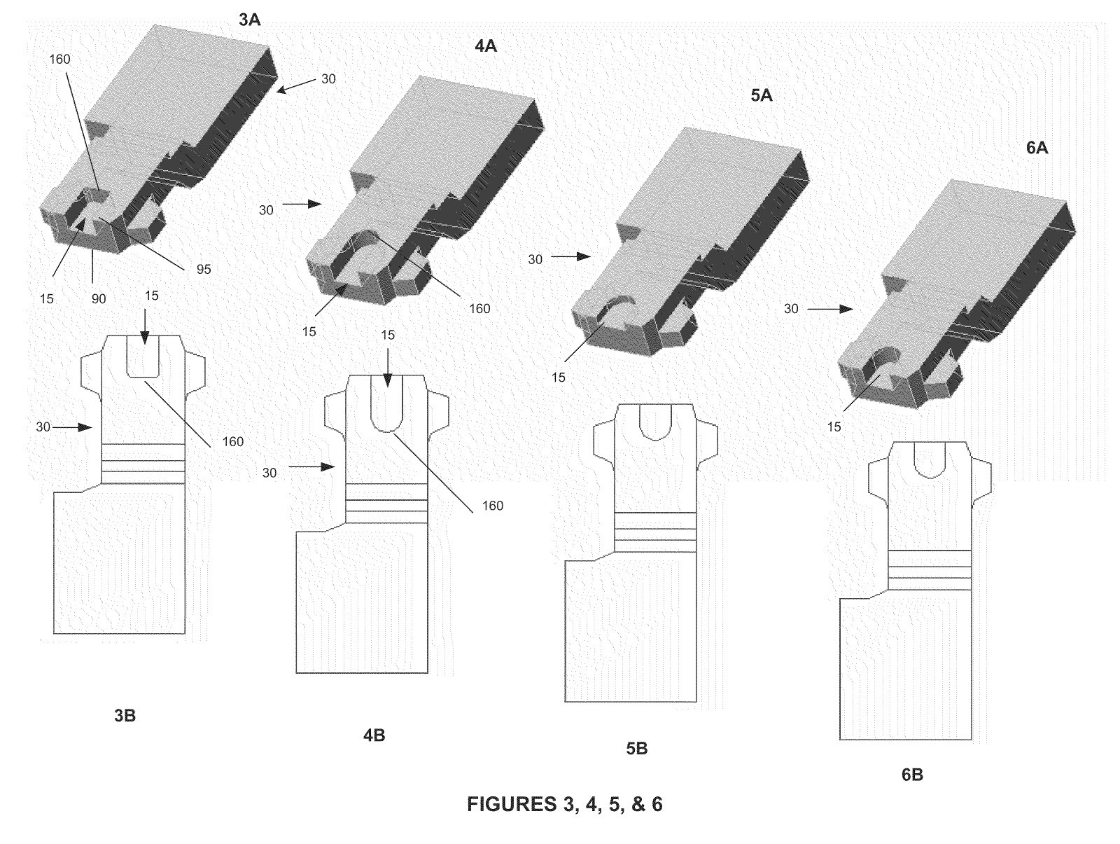

The proximal end 160 of a lead intrusion 15 may have any shape that aids to increase solder joint reliability. For instance, the proximal end 160 of a lead intrusion 15 may be substantially square shaped, rounded, curved, triangular, ellipse, polygonal, or any other desired shape. FIGS. 3A and 3B, for example, show that the proximal end 160 of a lead intrusion 15 may be substantially square shaped. Similarly, FIGS. 4A and 4B illustrate, that the proximal end 160 of the lead intrusion 15 may be substantially rounded. FIGS. 4A, 5B, 6A, and 6B illustrate other shapes that can be used.

The space between the proximal end 160 and the distal end 165 of the lead intrusion 15 may be any shape and size that increases solder joint reliability. For example, a cross section (not shown in the Figures) of the lead intrusion 15 between the proximal end 160 and the distal end 165 may have a shape and a size that are substantially similar to the shape and size of the profile of the intrusion 15 at the edge of the lead finger 30 where the intrusion extends (e.g., the distal side surface 105). For instance, the lead intrusion 15 that has a substantially rectangular-shaped profile at the distal side surface 105 of the lead finger 30 may have a cross section that is of a substantially similar shape and size. However, in another example, the space between the proximal end 160 and the distal end 165 of the lead intrusion may have cross sections that vary from the shape and size of the profile of the intrusion lead 15 at the distal side surface 10 of the lead finger 30. In this example, the lead intrusion 15 may narrow from its distal end 165 to its proximal end 160, and vice versa.

The lead intrusion 15 as a whole may be any size that allows the lead intrusion 15 to increase the solder joint strength and/or act as a stopper to prevent solder crack propagation. For instance, the lead intrusion 15 may have any suitable width X, where the width X may be measured as the distance between the first side 150 and the second side 155 of the lead intrusion 15, as shown in FIG. 4. For instance, the lead intrusions 15 may have a width X that is between about ⅕ and about ½ the width of the lead finger 30, where the width of the lead finger 30 may be measured as the distance between the first side 140 and the second side 145 of the lead finger 30. FIG. 2, for example, shows that the lead intrusion 15 may have a width X that is a little less than about ½ of the distance between the first side 140 and the second side 145 of the lead finger 30.

The lead intrusion 15 may also have any suitable height Y, where the height Y may be measured as the distance between the lower surface 95 of the lead finger 30 and the upper surface 170 of the lead intrusion 15. In some embodiments, the height Y of the lead intrusion 15 may be between about ⅕ and about ½ the height of the lead finger 30, where the height of the lead finger 30 may be measured as the distance between the lower surface 95 and the upper surface 90 of the lead finger 30. For example, 5A depicts a lead finger 30 with a shallow lead intrusion 15 that is approximately ⅕ the distance between the upper 90 and lower 95 surfaces of the lead finger 30. Similarly, FIG. 2 illustrates a lead finger 30 with a lead intrusion 15 that has a height Y that is about ½ the distance between the upper surface 90 and the lower surface 95 of the lead finger 30.

The lead intrusion 15 may also have any suitable depth Z, where the depth Z is measured as the distance between the proximal end 160 and the distal end 165 of the lead intrusion 15. In this example, the distal end 165 of the lead intrusion 15 and the distal side surface 105 of the lead finger 30 coincide. FIG. 2 illustrates that where the lead intrusion 15 extends to the distal side surface 105 of the lead finger 30, the lead intrusion 15 may have a depth Z that is about ¼ to about ¾ the length of the externally exposed lower surface 95, where the length of the externally exposed lower surface is the distance between the distal side surface 105 of the lead finger and the proximal end surface 138 of the externally exposed lower surface 95 of the lead finger 30. In this example, the proximal end surface 138 of the externally exposed lower surface 95 of the lead finger 30 may be determined as the part of the lead finger 30 that is closest to the die pad but is exposed from the encapsulation material 40 and is shaped to contact the external surface 200.

The lead intrusions 15 may be formed by any method or technique that allows them to open from the lower surface 95, as well as to extend to and open from an edge of the lead finger 30. For instance, some non-limiting examples of suitable methods of forming the lead intrusion 15 may include molding, chemical etching, mechanical stamping, or photoengraving.

The lead intrusions 15 may be formed in any location of the lead finger that is suitable to connect the package 10 to any desired external surface. For example, as previously explained, a lead intrusion 15 may be disposed on the lower surface 95 of a plurality of lead fingers 30. Indeed, where the lead intrusion 15 is disposed on the lower surface 95 of a lead finger 30, lead intrusions 15 may be disposed on any and/or all of the lead fingers 30 of the semiconductor package 10. For example, the Figures illustrate that all the lead fingers 30 of the semiconductor package may have a lead intrusion 15 extending to the distal side surface 105 of each lead finger 30.

In addition to the previously mentioned characteristics, the lead intrusions 15 may have any other characteristic that may increase the strength of the solder joint or the electrical connection between the semiconductor package 10 and the external surface. For instance, in some embodiments, the lead intrusions 15 may be coated with a conductive material such as silver or gold in order to improve the electrical connection between the semiconductor package 10 and the external surface. In another example of a possible variation on the lead intrusions 15, the lead intrusions may be a multi faceted shape so as to increase the surface area of the solder to the lead.

The semiconductor package 10 and any desired component may be manufactured by any suitable method or technique known in the art. In some embodiments, the integrated circuit chip 20 is manufactured as known in the art. Next, the leadframe containing the die pad 25 and the lead fingers 30 are made by any known process. The intrusions 15 are made in the lead fingers by chemical etching and/or stamping where a mask is first applied to the lead frame stock. Chemical etching is then performed on both surfaces of the lead frame stock to form the lead fingers and other features of the lead frame. The intrusions are then formed on the bottom side of the lead finger on a surface that is opposite a non-etched area of the opposing surface.

Next, the integrated circuit chip 20 is then attached to the die pad 25 of the leadframe. This process can be performed using any technique known in the art, such as solder paste printing, epoxy or solder dispensing, or soft solder wire. Then, the wire bonds 35 are then provided to connect the chip 20 to the lead fingers 30 using any process known in the art.

Next, a molding material is provided to encapsulate the device as known in the art. Once these processes are performed, the devices are singulated as known in the art. Then, the singulated semiconductor packages may be electrically tested. After electrical testing, the molding material in the semiconductor packages may be laser marked. Finally, the devices may be taped and reeled as known in the art.

The semiconductor packages 10 with the lead intrusions 15 may be used in any suitable electronic apparatus or device known in the art. By way of non-limiting examples, the semiconductor package 10 with lead intrusions may be used in any type of electronic device including those mentioned above, as well as chip on lead DFN/QFN, flip chip DFN/QFN, and all leadless packages.

The semiconductor package 10 with the lead intrusions 15 offer several advantages. For instance, the lead intrusions 15 may allow a larger surface area of the exposed lower surface 95 of the lead fingers 30 to which solder (or other bonding material) may be applied to attach the semiconductor package 10 to a surface of the desired device. Accordingly, the lead intrusions 15 may allow for a higher amount of solder bonded area, longer crack propagation length, and can stop or reduce the growth of a solder crack.

A second advantage relates to out-gassing. As mentioned, because the lead intrusions 15 extend to an edge of the lead finger 30, the lead intrusions 15 can provide a path for out-gassing during solder reflow. This venting can reduce solder void and further serve to strengthen the solder joint between the lead finger and the surface to which it is connected.

Another advantage includes the ability of the lead intrusions 15 to act somewhat like a capillary tube. For example, solder may fill the space between the lead intrusion 15 and the external surface through capillary action. The solder may line the lead intrusion 15 through adhesion and fill the space between the lead intrusion 15 and the external surface through solder cohesion. This capillary action may make it easier to form solder fillet at one or more of the edges of the lead fingers 30. In turn, a proper solder fillet at one or more of the edges of the lead finger 30 may further increase solder joint reliability.

In other words, the lead intrusions 15 increase the ease of semiconductor package 10 mounting as well as increase solder joint reliability. For example, in a comparison between a conventional lead finger with an externally exposed flat lower surface and a lead finger 30 with the lead intrusion 15 disposed on its externally exposed lower surface 95, while the solder stress remains the same, the creep and plastic strain of solder joint between the two surfaces, as well as the total solder plastic work, were all reduced. The lead finger 30 with the lead intrusion 15 had a range of about 10% to about 30% improvement in the plastic work (ΔW) over the conventional lead finger.

Having described the preferred aspects of the devices and associated methods, it is understood that the appended claims are not to be limited by particular details set forth in the above description, as many apparent variations thereof are possible without departing from the spirit or scope thereof.

1. A lead finger for a semiconductor device containing an integrated circuit chip, the lead finger containing an intrusion disposed on an exposed lower surface of the lead finger so that the lead intrusion opens from the exposed lower surface and extends to and opens from an edge of the lead finger.

2. The lead finger of claim 1, wherein the lead intrusion comprises a proximal end that is substantially rounded, ellipse, or square shaped.

3. The lead finger of claim 1, wherein the lead intrusion comprises a height that is about ⅓ to about ½ the height of the lead finger.

4. The lead finger of claim 1, wherein the lead intrusion comprises a width that is about ⅕ to about ½ the width of the lead finger.

5. The lead finger of claim 1, wherein the lead intrusion comprises a depth that is about ¼ to about ¾ the length of the lower surface of the lead finger.

6. A semiconductor package, comprising:
an integrated circuit chip attached to a die pad; and
multiple lead fingers connected to the integrated circuit chip by wire bonds, wherein one of the multiple lead fingers comprises an intrusion disposed on an exposed lower surface of the lead finger so that the lead intrusion opens from the exposed lower surface and extends to and opens from an edge of the lead finger.

7. The semiconductor package of claim 6, wherein the lead intrusion extends to and opens from a distal side surface of the lead finger.

8. The semiconductor package of claim 6, wherein the lead intrusion comprises a proximal end that is substantially rounded, ellipse, or square shaped.

9. The semiconductor package of claim 6, wherein the lead intrusion comprises a height that is about ⅓ to about ½ the height of the lead finger.

10. The semiconductor package of claim 6, wherein the lead intrusion comprises a width that is about ⅕ to about ½ the width of the lead finger.

11. The semiconductor package of claim 6, wherein the lead intrusion comprises a depth that is about ¼ to about ¾ the length of the exposed lower surface of the lead finger.

12. The semiconductor package of claim 6, wherein every lead finger contains an intrusion.

13. An electronic apparatus containing a semiconductor package, the semiconductor package comprising:
an integrated circuit chip attached to a die pad;
multiple lead fingers connected to the integrated circuit chip by wire bonds, wherein one of the multiple lead fingers comprises an intrusion disposed on an exposed lower surface of the lead finger so that the lead intrusion opens from the exposed lower surface and extends to and opens from an edge of the lead finger and wherein the lead intrusion extends to and opens from a distal side surface of the lead finger; and
an electrical device containing a surface to which the lead finger is connected.

14. The apparatus of claim 13, wherein the lead intrusion comprises a height that is about ⅓ to about ½ the height of the lead finger.

15. The apparatus of claim 13, wherein the lead intrusion comprises a width that is about ⅕ to about ½ the width of the lead finger.

16. The apparatus of claim 13, wherein the lead intrusion comprises a depth that is about ¼ to about ¾ the length of the exposed lower surface of the lead finger.

17. The apparatus of claim 13, wherein the electrical device comprises a printed circuit board.

18. The apparatus of claim 13, wherein every lead finger comprises an intrusion.

19. A method of making a semiconductor package, comprising:
providing an integrated circuit chip;
connecting the integrated circuit chip to a die pad;
connecting the integrated circuit chip to a lead finger so that the integrated circuit chip is electrically connected to the lead finger; and
forming a lead intrusion on lower surface of the lead finger so that the lead intrusion opens from the lower surface and extends to and opens from the distal side surface of the lead finger.

20. The method of claim 19, wherein the lead intrusion comprises a height that is about ⅓ to about ½ the height of the lead finger.

21. The method of claim 19, wherein the lead intrusion comprises a width that is about ⅕ to about ½ the width of the lead finger.

22. The method of claim 19, wherein the lead intrusion comprises a depth that is about ¼ to about ¾ the length of the lead finger.

23. The method of claim 19, further comprising encapsulating the integrated circuit chip, the die pad, and the lead finger.

24. The lead finger of claim 1, wherein the intrusion has a scalloped or a multi-faceted shape on its surface.

25. The semiconductor package of claim 6, wherein the intrusion has a scalloped or a multi-faceted shape on its surface.
